(19) United States
(12) Patent Application Publication
(10) Pub. No.: US 2012/0248402 A1
(43) Pub. Date: Oct. 4, 2012

(54) PHOTON EMITTER EMBEDDED IN METALLIC NANOSLIT ARRAY

(75) Inventors: Ronen RAPAPORT, Tel Aviv (IL); Shira YOCHELIS, Ness Ziona (IL); Yossef PALTIEL, Maskeret Batya (IL); Uri BANIN, Mevasseret Zion (IL)

(73) Assignee: YISSUM RESEARCH DEVELOPMENT COMPANY OF THE HEBREW UNIVERSITY OF JERUSALEM, LTD., Jerusalem (IL)

(21) Appl. No.: 13/432,802

(22) Filed: Mar. 28, 2012

Related U.S. Application Data
(60) Provisional application No. 61/468,903, filed on Mar. 29, 2011.

(51) Int. Cl. H01L 33/04; H01L 33/48

(52) U.S. Cl. 257/10; 438/26; 257/E33.005; 257/E33.056

(57) ABSTRACT

An emitter device for emitting electromagnetic radiation is presented. The device includes a metallic patterned structure, and emitting media integral with the metallic patterned structure. The emitting media includes one or more emitters of omni-directional emission in nature wherein certain emission pattern. One or more parameters of the metallic patterned structure, that define a dispersion map thereof, are selected according to the emitting pattern such that the metallic patterned structure operates as a beam shaper creating resonant coupling of each emitter with a microscopic confined optical mode of the metallic patterned structure thereby enhancing by a predetermined enhancement factor the emission from the emitting media in a predetermined direction. The device thus provides predetermined directional beaming of output electromagnetic radiation wherein a predetermined angular propagation of the electromagnetic radiation emitted by the emitting media.

### REFERENCES

The following references are considered to be pertinent for the purpose of understanding the background of the present invention:
[1] Nikhil Ganesh, Wei Zhang, Patrick C Mathias, Edmond Chow, J a N T Soares, Viktor Malyarchuk, Adam D Smith, and Brian T Cunningham. Enhanced fluorescence emission from quantum dots on a photonic crystal surface. Nature nanotechnology, 2(8):515-20, 2007.
[2] T W Ebbesen, H J Lezec, H F Ghaemi, T Thio, and P A Wolff. Extraordinary optical transmission through sub-wavelength hole arrays. Nature, 391(6668):667-669, 1998.
[3] Young Chul Jun, Ragip Pala, and Mark L. Brongersma Strong Modification of Quantum Dot Spontaneous Emission via Gap Plasmon Coupling in Metal Nanoslits. The Journal of Physical Chemistry C, 114(16):7269-7273, April 2010.
[4] M. G. Harats, R. Rapaport, Adiel Zimran, Uri Banin, and G. Chen. Enhancement of two photon processes in quantum dots embedded in subwavelength metallic gratings. Arxiv preprint arXiv:1011.3894, pages 1-14, 2010.
[5] a. G. Curto, G. Volpe, T. H. Taminiau, M. P. Kreuzer, R. Quidant, and N. F. van Hulst. Unidirectional Emission of a Quantum Dot Coupled to a Nanoantenna. Science, 329(5994):930-933, August 2010.
[6] F J Garcia-Vidal and L Martin-Moreno. Transmission and focusing of light in one-dimensional periodically nanostructured metals. Physical Review B, pages 1-10, 2002.
[7] Ilai Schwarz, Nitzan Livneh, and Ronen Rapaport. A unified analytical model for extraordinary transmission in subwavelength metallic gratings. Andy preprint arXiv:1011.3713, pages 1-7, 2010.
[8] Nanfang Yu, Jonathan Fan, Qi Jie Wang, Christian Pfl\ddot{}ugl, Laurent Diehl, Tadataka Edamura, Masamichi Yamanishi, Hirofumi Kan, and Federico Capasso. Small divergence semiconductor lasers by plasmonic collimation. Nature Photonics, 2(9):564-570, July 2008.
[9] M. Treacy. Dynamical diffraction explanation of the anomalous transmission of light through metallic gratings. Physical Review B, 66(19):1-11, November 2002.

### BACKGROUND

The miniaturization of photonic devices requires new ways to manipulate light, down to the single photon limit, using tiny optical elements. An excellent example for nano-emitters are nanocrystal quantum dots (NQDs), that can be used essentially as single photon sources and are considered as building blocks for optical quantum information devices. Various works have explored the possibilities of manipulating NQDs optical properties using various kinds of dielectric nanostructures [1]. Since the pioneering work of Ebbesen et. al [2] showing extraordinary transmission (EOT) from subwavelength metallic hole arrays, there is a fast growing interest in metallic nanostructures as tools for manipulating electromagnetic (EM) radiation on the nanoscale [3,4,5].

### GENERAL DESCRIPTION OF THE INVENTION

There is a need in the art for tiny active elements for emission and absorption of photons, and means to manipulate this light locally on the same subwavelength lengthscale. Current methods for extraction and harvesting photons from quantum dots are generally not well controlled.

The present invention provides a novel approach enabling manipulation of the direction of the emitted photons. The inventors have created a novel integrated device (e.g. nanostructure) configured for directional emission of electromagnetic radiation within a substantially narrow emission angle, e.g. of a few degrees. The device of the invention includes an emitter, which is of omni-directional emission by nature (i.e. before being incorporated in the structure of the invention) embedded in a metallic array structure. The metallic array structure is formed by a pattern of spaced-apart metallic features (e.g. grid) embedded in a dielectric structure, which is a single- or multi-layer dielectric structure. Such a metallic array structure is referred to herein as metallic nanoslit array or metallic patterned structure.

Thus, the device of the invention comprises a metallic patterned structure carrying a photon emitter. For example, this may be a layer containing a single nanocrystal quantum dot (NQD) or multiple NQDs coupled to a metallic nanoslit array. Generally, the emitter may be any media, i.e. discrete elements or bulk, capable of emitting photons in one or more wavelength ranges (e.g. in response to exciting external radiation). This may be quantum dot(s), quantum well(s), quantum wire(s), bulk emitter. The emitter media may be a separate layer coupled to the metallic nanoslit array, or may be media incorporated/embedded in the dielectric structure of the metallic slit array. The emitter media (emitter containing layer) is an omni-directional emitter by nature for certain wavelength range, i.e. before being incorporated in the metal grid structure, and incorporation thereof into the metal grid structure results in that the entire device emits electromagnetic radiation of said wavelength range in a desired direction and with a desired divergence of the emitted beam.

According to the invention, certain parameters of the metallic nanoslit array are selected in accordance with the parameters of the emitter media to provide a desired directional emission of the device resulting from resonant coupling of the emitter (e.g., each of the QDs) to microscopic confined optical mode of the metallic nanoslit array. It should be understood that desired directional emission signifies desired direction and divergence angle, and desired emission spectrum. The parameters of the emitter media that are to be considered in this respect include the emitting pattern thereof, e.g. wavelength range, emitters' distribution in the emitter containing layer, thickness of said layer. The parameters of the metallic nanoslit array that are to be selected include those defining a dispersion map of the metallic nanoslit array, for example critical dimensions of the pattern and/or fill factor or density of the metallic features, material composition of the metallic grid and/or dielectric layers, as well as a number of dielectric layers and thickness thereof. This resonant coupling of the emitter to microscopic confined optical mode of the metallic nanoslit array results in coupling of the confined optical modes of the metal grid structure to plane waves propagating through and out of the structure, providing that emission of said emitter in directions/angles outside the desired one is substantially suppressed in favour of emission in the desired direction, i.e. causes a narrow-angle directional emission of said emitter, which emission would otherwise distributed in multiple directions. Thus, the metallic nanoslit array is configured as a beam shaper or beaming structure which directs substantially all the emitted energy with a desirably narrow angle along a desired general direction of propagation.

The inventors have demonstrated a directional beaming (narrow divergence angle of emitted beam with a specific general direction of propagation) of single or multiple photons emitted from nanocrystal quantum dots embedded in a subwavelength metallic nanoslit array, e.g. with a divergence angle of less than 4 degrees. The inventors have shown that the eigenmodes of the structure result in localized electromagnetic field enhancements at the Bragg cavity resonances, which could be controlled and engineered in both real and momentum space. The photon beaming is achieved using the enhanced resonant coupling of the emitter (quantum dots) to these Bragg cavity modes, which dominates the emission properties of the quantum dots. The inventors have shown that the emission probability of a quantum dot into the narrow angular mode is 20 times larger than the emission probability to all other modes. This can be used to engineer wavelength and angular selective emission of nano-emitters using the polarization, spatial, and angular selectivity of these resonant standing electromagnetic modes.

The inventors prepared two different experimental structures, and have shown such selectivity in both structures supporting different types of resonant modes. The simple calculations support the physical picture of enhanced optical dipole coupling due to a large enhancement of EM density of states at the extraordinary transmission (EOT) or surface plasmon polaritons (SPP) like resonances, which cause a preferred coupling of the optical dipoles to those modes which have a well defined angular directionality as well as defined polarization. Also, the inventors have shown that this beaming effect occurs on the single quantum dot photon level, which could be useful for exploiting such effects for a single photon based device for quantum information or other quantum optics applications. Generally, the invention can be used in active optical devices, where spatial control of the optical properties of the emitter(s), e.g. nano-emitters, is essential, on both the single and many photons level.

The inventors have identified a novel property of directional emission resulting from coupling of the emitter (e.g. each of the QDs independently) to the optical mode of the metallic array. The direction of photon emission and the divergence angle as well as wavelength range of the emitted beam are dependent on various parameters and conditions of the structure, including those of the metallic nanolist array and those of the emitter (NQDs) containing layer, such as critical dimensions and density of the features of the metallic grid and dielectric structure in which the grid is embedded. The coupling between the metallic nanolist array and the emitter(s), as well as density of the discrete emitters (QDs), controls the operating resonance wavelength, the number of photons emitted (single photon to multiphoton emission) and enhancement factor (a ratio between the photons emitted to the resonant mode and photons emitted to other, non-resonant modes). Proper selection of these parameters provides for creating resonant coupling of the optical transition of the emitter(s) to the EM mode of the metallic nanoslit array.

The emission from emitter layer and the behaviour of metallic slits have been investigated separately and in a combined structure. For example, polarized emission of NQDs, different for TE and TM polarization modes, can be enhanced using a metallic nanoslit. Also, spontaneous emission rate of NQDs can be altered using a metallic nanoslit. In nanoslit array structures, the resonant enhancement of nonlinear optical processes is due to the strong local electromagnetic field enhancements inside the structure at the EOT resonances [7]. The inventors have also shown that by placing NQDs onto a metallic nanoslit array, a large enhancement of two-photon absorption processes and of photon upconversion efficiency can be achieved [4].

As indicated above, one of the attractive applications of the technique of the invention is a single photon source. The main difficulty in realizing a high efficiency deterministic single photon source using quantum dots is the ability to collect all the emitted photons, as the quantum dot emission is essentially non-directional. Therefore an external device for directing these photons is necessary. Directional emission with a divergence angle of 12.5 degrees from NQDs was demonstrated by embedding them on a nanoscale Yagi-Uda antenna [5]

The present invention is based on the inventors' understanding of the physical mechanism of the coupling of a (nano)emitter to the EM resonant modes of metallic nanoslit array structures. Metallic nanoslit array structures have been shown to have a unique EM response, such as resonant EOT [2], resonant strong surface EM-field enhancements in subwavelength areas [6], and a well defined transmission and reflection band structure for incoming EM radiation [7]. The origin of these special optical properties have been a subject of intense research in recent years, and are in general a result of the selective resonant excitation, via Bragg diffraction, of standing optical Bloch modes in the periodic metallic structure [7]. It was shown that fabricating linear or circular arrays on top of a quantum cascade laser, the emitted coherent classical radiation could be directed with a small divergent angle [8].

The present invention provides a technique affecting the directionality of emission from an emitter, whose emission is otherwise omni-directional. The proper resonance coupling between the emitter and metallic nanoslit array provides highly directional emission of photons from the emitter/emitting media (e.g. NQDs) embedded in a metallic nanoslit array.

According to a broad aspect of the invention, it provides an emitter device for emitting electromagnetic radiation, wherein the device comprises a metallic patterned structure, and emitting media integral with the metallic patterned structure, wherein the emitting media comprises one or more emitters each of omni-directional in nature and has certain emission pattern, and one or more parameters of the metallic patterned structure defining a dispersion map thereof are selected according to said emitting pattern such that the metallic patterned structure operates as a beam shaper creating resonant coupling of each of said one or more emitters of the emitting media with a microscopic confined optical mode of the metallic patterned structure thereby enhancing by a predetermined enhancement factor emission from emitting media in a predetermined direction, the device thereby providing predetermined directional beaming of output electromagnetic radiation emitted by the emitting media characterized by a predetermined angular propagation of the output electromagnetic radiation.

The emitting media may comprise a layer containing at least one emitter embedded therein, such as quantum dot, or quantum wire, or quantum well, or a bulk material. This layer may be located on an outer surface of the metallic patterned structure (top or bottom surface), or may be embedded in a dielectric layer structure of said metallic patterned structure, being above or below the metallic pattern or in between the metallic features.

The emitting media may be active media responsive to a predetermined excitation, such as an optically pumped media or electrically pumped media which emits electromagnetic radiation of a certain emitting pattern in response to exciting (pump) radiation or in response to applied electromagnetic field.

One or more parameters of the metallic patterned structure are selected to provide said beam shaping. These parameters may include at least one of the following: critical dimensions of the metallic pattern; density of the metallic features of said pattern, material composition of the metallic patterned structure including material composition of the dielectric layers, layout of said metallic patterned structure.

The directional photon beaming is achieved using the resonant coupling of the optical transitions of the emitter media to a metallic nanoslit array. A divergence angle of a few degrees (e.g. 3.4 degrees) was found. The inventors have shown that this directional emission results from a coupling of a single nanoemitter to the macroscopic confined optical mode of the metallic nanostructure. This coupling is a wavelength selective, a polarization, and a position selective process, allowing a good control of the desired optical properties. The experimental results were compared to calculations of the excited structure resonant modes and of a dipole-cavity resonant coupling in order to elucidate the underlying process responsible for the photon beaming effect.

According to another aspect of the invention, it provides an emitter device for directional emission of electromagnetic radiation propagating in a predetermined direction and a predetermined angular distribution, the device comprising emitting media for emitting electromagnetic radiation with a certain emitting pattern, the emitting media comprising one or more emitters each of omni-directional emission in nature embedded in a metallic patterned structure, wherein the metallic pattern structure has a predetermined dispersion map selected according to the emitting pattern of the emitting media such that each of said one or more emitters of the emitting media is in resonant coupling with a microscopic confined optical mode of the metallic patterned structure, a device output being formed by said electromagnetic radiation propagating with the predetermined direction and the predetermined angular distribution.

According to yet further aspect of the invention, there is provided an emitter device comprising emitting media for emitting electromagnetic radiation with a certain emitting pattern, the emitting media comprising one or more emitters each of omni-directional emission in nature embedded in a metallic patterned structure, wherein the metallic pattern structure has a predetermined dispersion map selected according to the emitting pattern of the emitting media to provide beam shaping to radiation being emitted characterized by at least one of the following: polarized emission of the emitting media having different general direction of propagation and angular distribution for TE and TM polarization modes, altering spontaneous emission rate of the emitting media, and a desired number of photons in an output beam of the device.

According to yet another aspect of the invention, there is provided a radiation source system comprising the above-described emitter device, and an exciting unit (e.g. light source or electromagnetic field generator) configured and operable to excite the emitting media to emit said electromagnetic radiation with said emitting pattern.

According to yet another broad aspect of the invention, there is provided a method for providing predetermined directional beaming of electromagnetic radiation having a predetermined angular propagation of the electromagnetic radiation, the method comprising:

selecting emitting media formed by one or more emitters of omni-directional emission in nature having a predetermined emitting pattern;

providing a metallic patterned structure of a predetermined dispersion map selected in accordance with said emitting pattern; and

integrating said emitting media in said metallic patterned structure, thereby creating resonant coupling of each of said one or more emitters of the emitting media with a microscopic confined optical mode of the metallic patterned structure thereby enhancing by a predetermined enhancement factor the emission from the emitting media in a predetermined direction and angular distribution.

The dispersion map of the metallic patterned structure may be selected to provide polarized emission of the emitting media different for TE and TM polarization modes, and/or altering spontaneous emission rate of the emitting media, and/or providing a desired number of photons in an output beam of the device.

### BRIEF DESCRIPTION OF THE DRAWINGS

The patent or application file contains at least one drawing executed in color. Copies of this patent of patent application publication with color drawing(s) will be provided by the Office upon request and payment of the necessary fee. In order to understand the invention and to see how it may be carried out in practice, embodiments will now be described, by way of non-limiting example only, with reference to the accompanying drawings, in which same reference numerals are used to identify elements or acts with the same or similar functionality, and in which:

FIG. 1a shows an example of the configuration of a directional emitter device of the present invention;

FIG. 1b shows the angular transmission spectrum of a TE polarized light through the device of FIG. 1a;

FIG. 1c shows another example of the configuration of a directional emitter device of the present invention;

FIG. 1d shows the angular transmission spectrum of a TM polarized light through the device of FIG. 1c;

FIG. 1e shows the photoluminescence spectrum of the 8 nm InAs/CdSe nano dots in a solution;

FIGS. 1f and 1g show the AFM and SEM images of a grating surface coated with organic monolayer of MPdS to which 8 nm core/sell InAs/CdSe nanoparticles are attached for Al part (FIG. 1f) and glass part (FIG. 1g);

FIGS. 1h and 1i present XPS spectra of a sample with and without InAs/CdSe nanoparticles;

FIGS. 2a to 2c exemplify measurement of angular emission spectrum of the embedded emitter media (NQDs), where FIG. 2a shows the schematics of an experimental setup, FIG. 2b shows the configuration of a reference sample similar to that of FIG. 1a with exactly the same parameters as in the sample under measurements but without a nanoslit array, and FIG. 2c presents the TE polarized angular emission spectrum from the sample with the nanoslit array under the same excitation conditions as for the reference sample;

FIGS. 3a to 3c present the TE polarized angular emission intensity from the nanoslit array sample and the reference sample at a specific wavelength, demonstrating strong spatial selectivity in the enhancement of the coupling of the NQD optical dipole transition to the resonant EM modes of the nanoslit array;

FIGS. 4a to 4d show experimental results carried out with the sample configured similar to that of FIG. 1c, where FIGS. 4a and 4b show the measured TM polarized angular emission spectra of the sample when the laser excitation is from the top of the sample and from the glass side respectively, FIG. 4c field enhancements localized close to the air-metal interface, and FIG. 4d shows field intensity distribution cross sections;

FIG. 5 exemplifies the geometry of the patterned metallic structure used in the device of FIG. 1a, and all relevant optical and material parameters;

FIG. 6 is a schematic illustration of the EBC model, showing (a) numerically calculated near-field intensity in a unit cell of the grating in three different configurations, and (b) corresponding EBC model mapping;

FIG. 7 shows numerically calculated zero-order transmission in the TM polarization with no added thin dielectric layer, in the symmetric configuration n₁=n₃=nₛ, for different wavelengths and grating thicknesses;

FIG. 8 shows a similar graph for the TE polarization, where a thin dielectric layer was added; and

FIG. 9 exemplifies dependency of the device transmission on the slit width (space between the metallic features) showing that by changing the slit width the properties of the evanescent wave in the slits can be changed.

### DETAILED DESCRIPTION OF EMBODIMENTS

The present invention provides a photon emitter device configured and operable to provide the directional photon beaming. In the description below, a one dimensional photon beaming is exemplified. However, it should be understood that the same concept can be used to extend the directionality into two dimensions.

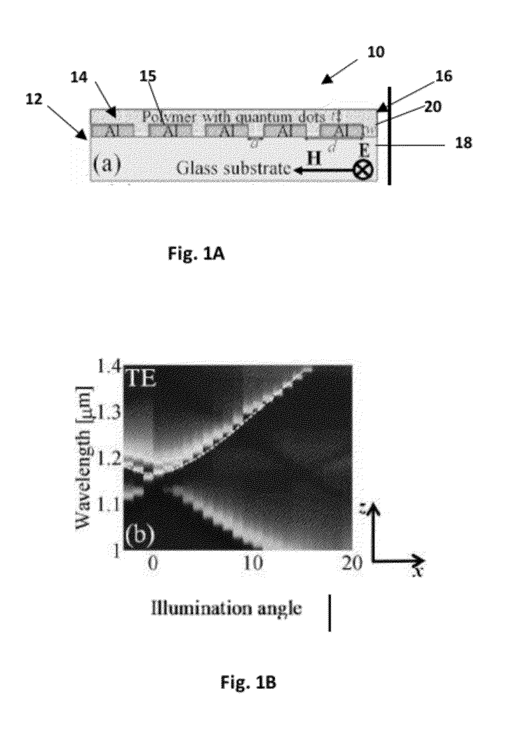

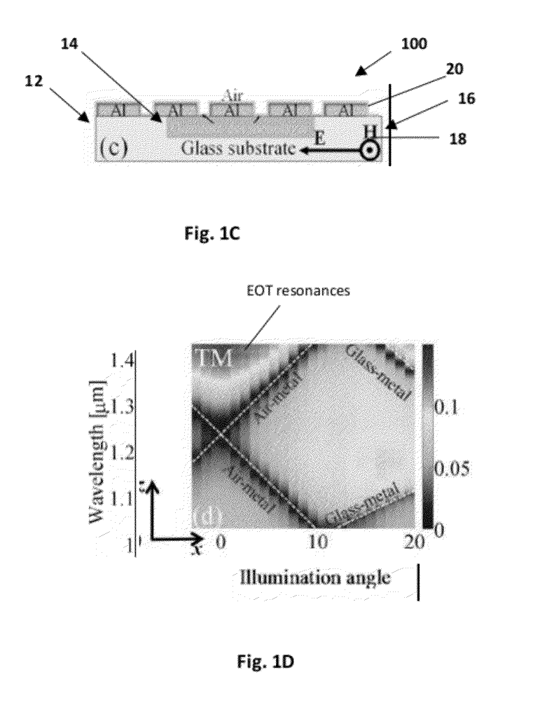

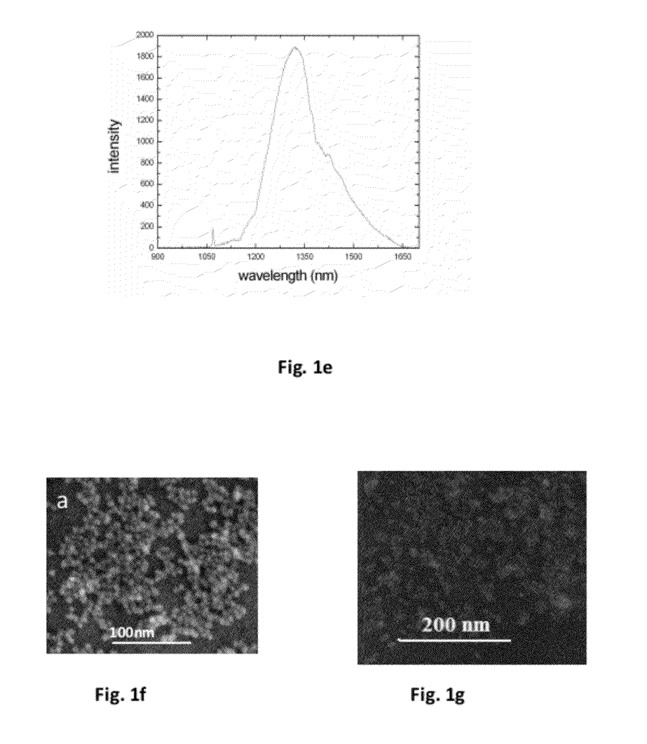

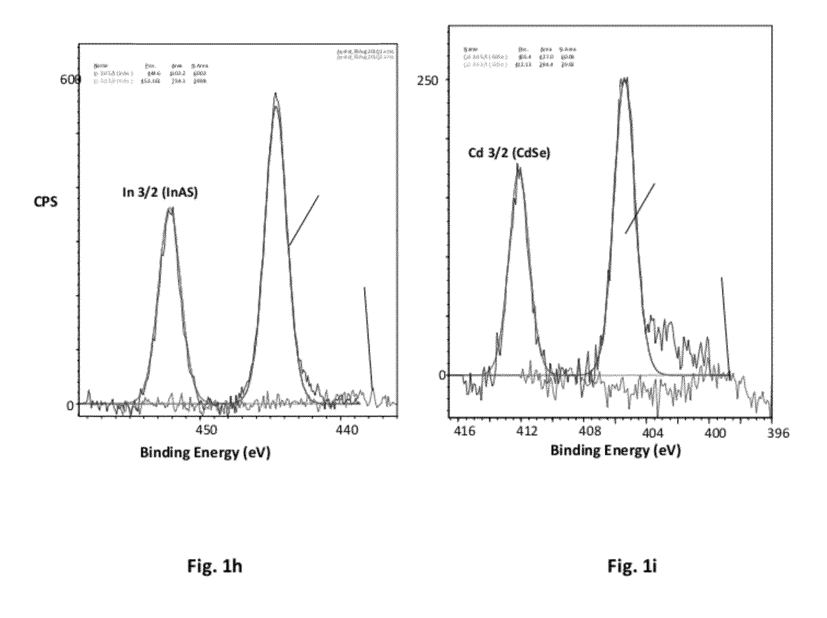

Two specific but not limiting examples of a device of the present invention are shown in FIGS. 1a and 1c. The same reference numbers are used for identifying components that are common in all examples.

A device 10 of FIG. 1a includes a nanoslit array structure 12 and emitter media 14. The nanoslit array structure 12 is in the form of a metal (e.g. Al) grating 15 with a thickness of 250 nm embedded in a dielectric structure 16. The latter is formed by a SiO₂ substrate 18 carrying the Al grating on top thereof, and a thin dielectric polymer (PFCB) layer 20 deposited on top of the grating structure. In the present example, the emitter media 14 is embedded in the dielectric structure 16 of the nanoslit array structure 12. The emitter media is in the form of NQDs containing layer, being the transparent polymer layer 20, with a thickness t≅200 nm, which contains a homogeneous dispersion of InAs/CdSe core/shell NQDs, with an estimated volume density of 4%.

A device 100 of FIG. 1e includes a nanoslit array structure 12 and emitter media 14. Here, the emitter media 14 is in the form of a monolayer of 8 nm core/shell InAs/CdSe NQDs attached to the surface of a bare grating structure 16, by first binding a monolayer of short organic molecules to the surface of the grating, followed by a selective binding of the NQDs to the organic monolayer. This forms a dense monolayer of NQDs with estimated average NQD surface density of ˜10¹² cm⁻².

FIG. 1e shows the photoluminescence spectrum of the 8 nm InAs/CdSe nano dots in a solution. The adsorption of the dots was done in the same way for the Aluminum (Al) films and the glass substrate. Two types of organic molecules were used for forming the self assembled monolayers on the Al/glass film, 2-methylene-1,3-propanediyl)bis(trichlorosilane (MPdS), and 3-mercaptopropyl trimethoxysilane (MPS). All the chemicals were purchased from Sigma-Aldrich. The monolayer served as linker between the InAs/CdSe core/shell nanoparticles and the Al film. Before the adsorption procedure all substrates were cleaned with solutions of acetone and ethanol and then placed in plasma cleaner for 10 minutes. The cleaned Al film was placed in 1 mM solution of the organic linker dissolved in BCH. Following the adsorption of the organic linker, the samples were inserted into the nanoparticles solution for 4 hours. The adsorption process was performed inside a specially built nitrogen chamber.

FIGS. 1f and 1g show scanning electron microscopy (SEM) images of grating surface coated with organic monolayer of MPdS to which 8 nm core/sell InAs/CdSe nanoparticles were attached (FIG. 1f) Al part, (FIG. 1g) Glass part. The average coverage in this specific sample is 1·10¹² NPs/cm². The same density of dots coverage was achieved on the Al surface and glass surface. The density of the monolayer analyzed by AFM and SEM images (FIGS. 1f and 1g), on both films was the same without differentiating between the Al regions and the glass regions. The uniform density arises from the fact that the adsorption of the molecules takes place on oxidized surfaces, which apply both to the glass and oxidized Al.

FIG. 1h and 1i present XPS spectra showing that after the monolayer assembly, peaks of both In and Cd are identified on the sample. More specifically, the figures show X-ray photoelectron spectroscopy (XPS) spectra of the sample, where graph G1. represents the sample with InAs/CdSe nanoparticles and graph G2 represents the sample without nanoparticles. In FIG. 1h the existence of 1n on the organic monolayer was identified as indicated by the doublet peaks at binding energy of 444.6 eV and 452.2 eV. In FIG. 1h the existence of Cd on the organic monolayer was identified as indicated by the doublet peaks at binding energy of 405.4 eV and 412.1 eV. To characterize the transmission properties of both nanoslit configurations, angular dependent transmission measurements of a collimated white light source was performed.

The angular transmission spectrum of a TB polarized light through the device of FIG. 1a is shown in FIG. 1b. A clear EOT is observed, in which well defined high transmission resonant lines are seen.

The underlying mechanism responsible for such an EOT in TE polarization was recently explained by a formation of a standing wave of the Bragg diffracted incoming light in the dielectric layer on top of the metallic grating [7]. This light evanescently couple through the slits into the top dielectric layer. This standing wave of the higher Bragg modes interferes constructively with the Zero order mode, resulting in a Fabry-Perot cavity like resonance with a high forward transmission. Another consequence of such a cavity resonance is the enhancement of the EM field intensity inside the effective cavity [5]. In the case of an EOT of TE polarized light with a thin dielectric layer on top of the nanoslit array, this effective cavity is the dielectric layer. The predictions of the analytical model developed in Ref. [7] for the expected BOT resonances are marked by the dashed white lines in FIG. 1b.

A similar white light transmission measurement, but now in TM polarization, was performed on the device of FIG. 1b, and the corresponding angular transmission spectrum is shown in FIG. 1d. Here, a set of EOT resonances are seen. More importantly, a set of transmission minima are clearly observed. These minima correspond to the excitation of standing SPP-like modes, which in such structures only exist with TM excitation. Two sets of transmission minima are identified. The first, lower energy set marked by “glass-metal” in FIG. 1d, corresponds to the SPP on the glass-metal interface of the periodic structure. This SPP-like mode dispersion is given by:

k_{SPP}=kx+2mπ/d,

where

k_{SPP}(ω)=ω/c((∈ₘ·∈_{SiO}_{₂})/(∈ₘ+∈_{SiO}_{₂})),

kx=2πn_{SiO}_{₂}/λ sin(θ),

wherein λ is the wavelength of the light in vacuum, θ is the impact angle and ∈ₘ, ∈_{SiO}_{₂} are the dielectric constants of the metal and SiO₂ respectively, and n_{SiO}_{₂}, is the SiO₂ refractive index.

The second, higher energy set of minima lines, correspond to the SPP-like mode on the air-metal interface, with a similar dispersion relation to the one above but with the refractive index of air (nₐᵢᵣ) replacing n_{SiO}_{₂}. These SPP resonances are marked by “air-metal” in FIG. 1d. As opposed to the EOT resonance, exciting one of the SPP resonances results in a reflection of the excited light and therefore in minima in transmission. Similar to the device of FIG. 1a, the SPP's forms a standing wave in the structure that is characterized by strong local field enhancements. In the case of these SPP-like modes, the field enhancement is mostly located close to the corresponding dielectric metal interfaces (either glass or air). As will be described further below, these well defined angular dispersion and strong local EM field intensity amplification are important for the emission properties of the NQD's.

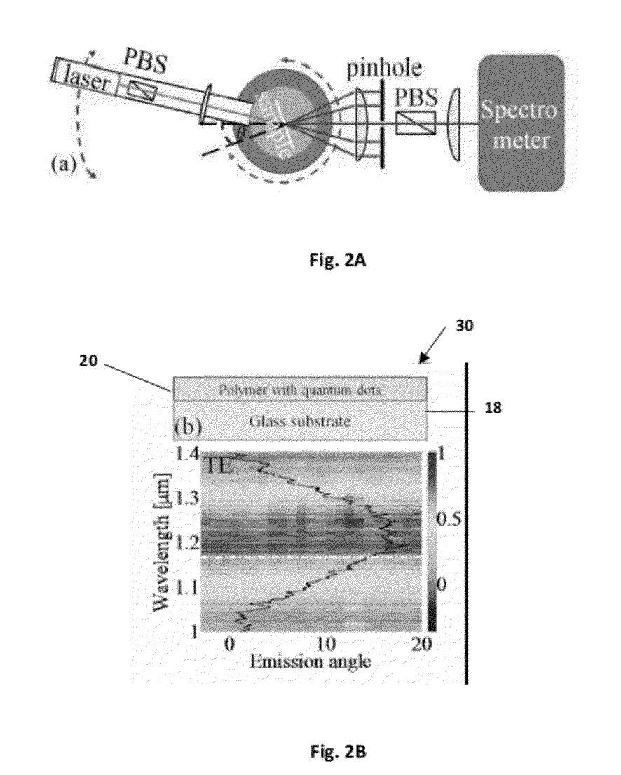

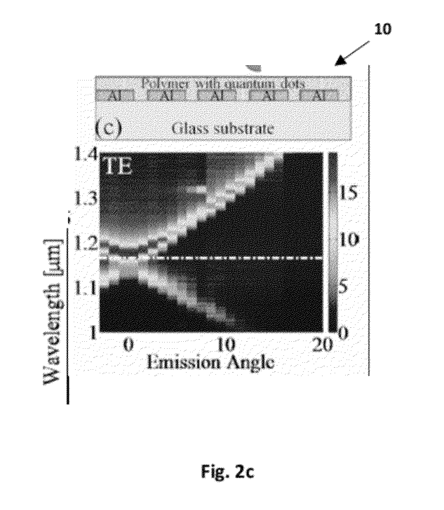

Reference is made to FIGS. 2a to 2c exemplifying measurement of angular emission spectrum of the embedded emitter media (NQDs). FIG. 2a which depicts the schematics of the experimental setup for the measurements of the angular emission spectrum of the embedded emitting media (NQDs). The angular emission was scanned by changing the angle of the sample normal with respect to the optical path from the sample to the spectrometer while keeping angle between the sample and the exciting laser fixed at 53°. FIG. 2b shows the configuration of a reference sample 30 having NQDs in a polymer layer 20 on glass 18 with exactly the same parameters as the sample, but without a nanoslit array (15 in FIG. 1a) and shows the angular emission spectrum from this reference sample. A typical emission spectrum of InAs/CdSe NQDs centered around 1.2 μm, with an inhomogeneous broadening of 200 nm FWHM is observed, as is seen in the emission cross-section at zero angle plotted by the black curve. No angular dependence was observed for both TE and TM polarizations, indicating a spherically symmetric emission pattern from the NQDs with no preferred emission direction, as is expected from randomly distributed spherical particles.

FIG. 2c presents the TE polarized angular emission spectrum from the nanoslit array sample 10 of FIG. 1a under the same excitation conditions as for the reference sample 30. The spectrum shown is normalized to the reference sample spectrum. In contrast to the reference sample, a clear angular dependence is observed, with narrow emission lines which are much stronger than the background emission, their angular spectral dispersion corresponds closely to the EOT transmission maxima of FIG. 1b. The emission from the back side of the nanoslit array sample 100 of FIG. 1c was also measured, and a similar directional angular emission spectrum was found (not shown), but with a much lower intensity.

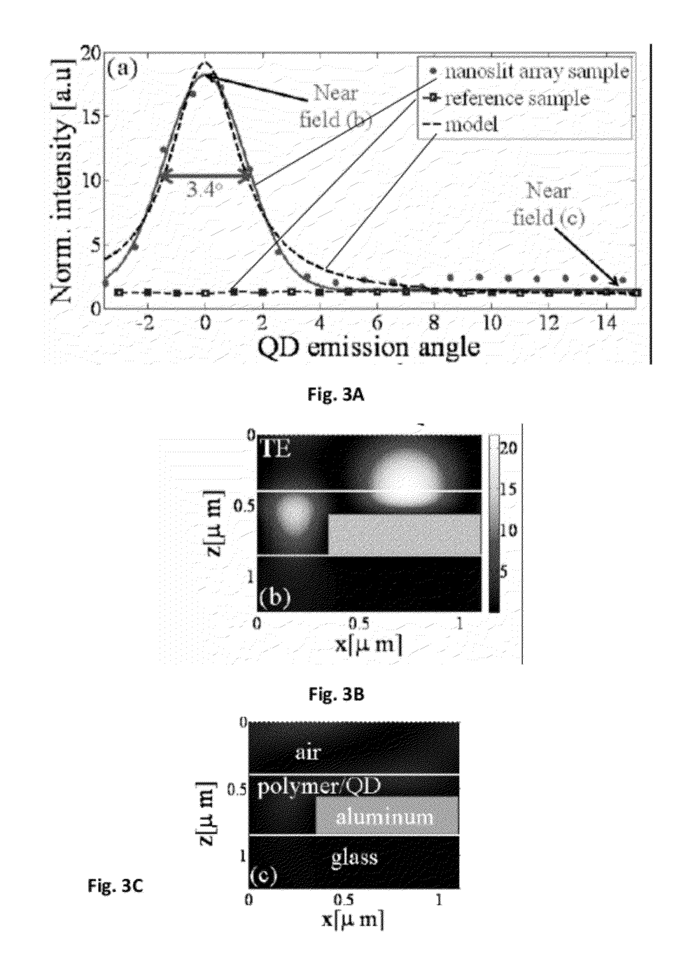

Reference is made to FIGS. 3a-3c presenting the TE polarized angular emission intensity from the nanoslit array sample 10 and the reference sample 30 at a specific wavelength marked by the dashed line in FIGS. 2b,c. This wavelength was chosen such that the emission from the nanoslit array sample is maximal in the forward direction (zero angle). The emission from the reference sample displays no angular dependence, while the emission from the nanoslit array sample shows a clear angular preference, with an emission peak at zero angle almost 20 time higher than the reference sample and a fitted angular divergence angle of 3.4 degrees FWHM. Therefore, the nanoslit array acts as a beaming device for causing the NQDs emission in a specific direction while preventing emission in other directions. For NQDs with a given emission wavelength, there is a preferred emission in the angular direction that corresponds to the EOT resonance at that wavelength.

To estimate the efficiency of this emission beaming, the percentage of the forward TE emission with divergence of ±3° from 0° was estimated, and compared to the measured total emission intensity at this wavelength into half circle of 180°, This number was found to be 21% of the total emission. It is important to note that the spontaneous emission of each NQD is independent of all the rest of the NQDs, thus this photon beaming effect is due to the coupling of each individual NQD to the optical modes of the whole structure, and not a collective effect of all the NQDs. To verify this point, the flux of photons emitted from the sample was estimated. The estimated photon flux R per NQD lifetime per NQD spectral bandwidth, R, is found to be R<0.05 [Photon/(τ_{NQD}·Δλ_{NQD}], where τ_{NQD} and Δλ_{NQD} are the NQDs emission lifetime and spectral bandwidth respectively. As R<<1, which means that at any point of time, there is only one NQD with a given emission wavelength emitting a photon. It is thus clear that the observed beaming effect happens on the single NQD level.

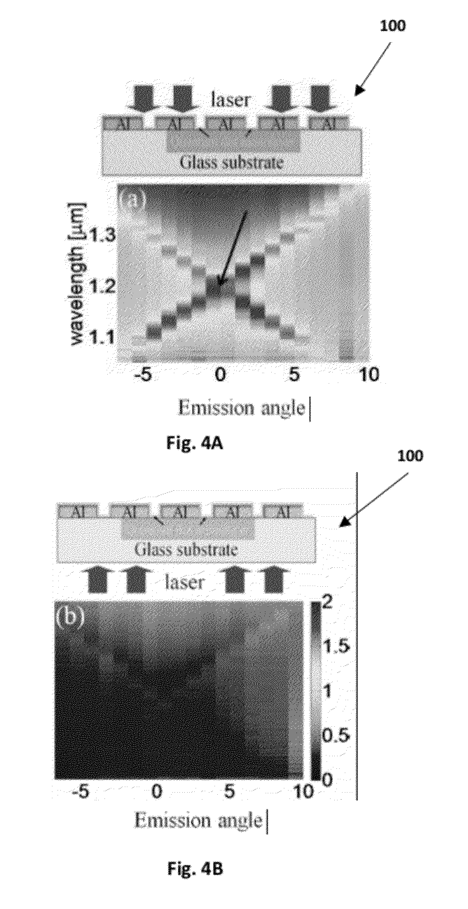

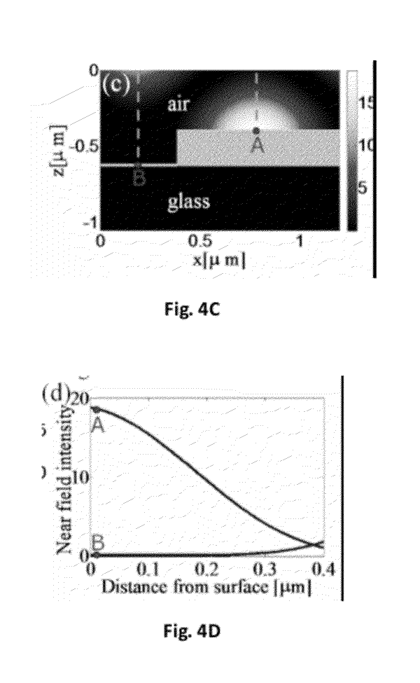

The similarity of the transmission and emission spectra in FIGS. 1b and 2c for the device 10 configuration of FIG. 1a and in FIGS. 1d and 4a for the device 100 configuration of FIG. 1c implies that the beaming effect is a result of coupling of the nanoemitters to the EM modes of the structure. This is expected due to the local enhancement of EM field intensities inside the structure at or near the EOT resonant wavelength, or in SPP-like reflection resonances. These resonances correspond to the structure's standing wave condition [7]. The emission probability of the NQD into these modes should then be enhanced compared to the probability of coupling into other leaky modes, such as leaky modes propagating along the slits or in other angles. This probability enhancement is related to the modification of the emission lifetime of optical dipoles in resonant structures, such as been observed lately for NQDs in single metal slits [3]. In a periodic nanoslit array structure, the EOT or SPP-like standing modes couple to free space with a particular angular and spectral dependence, given by the boundary conditions and the Bragg momentum conservation of the light [9]. These in turn dictate the light transmission dispersion shown in FIGS. 1e and 1d. To show this point more clearly, the transmission spectrum and the local fields in both the nanoslit array sample and the reference sample were calculated for an incident monochromatic plane wave in various incident angles and wavelengths. The calculation was done using a dynamical diffraction theory developed for such structures by in Ref. [9], and its results matches the transmission angular spectrum very accurately (as seen in FIG. 1b). In FIG. 3b the results of these calculations are shown for a unit cell of the periodic structure at the wavelength in which maximum emission is observed in the forward direction (i.e., zero emission angle, marked by the arrow in FIG. 3a). Strong field intensity enhancements are clearly seen inside the polymer/NQD layer, reaching a value which is 20 times larger than in free space. Therefore, a preferred emission of the NQDs into this mode that propagates normal to the structure is expected. For comparison, the field intensities calculation inside the polymer/NQD layer for an angle of 15 degrees, far away from the structure EOT resonance at this wavelength, is plotted in FIG. 3c. No significant field intensity enhancements are seen and therefore no preferred emission into a propagating mode in this angle is expected, as is indeed observed. This explains the large difference in the emission intensity to different angles and the beaming effect.

To be more quantitative, the relative angular emission efficiency can be calculated using a model of dipole-cavity coupling in the weak coupling limit, known as the Purcell effect. The standing EM resonances are approximated by a Lorentzian in the frequency domain. Under this assumption, the coupling rate of the NQD to the resonant mode (W_{cavity}) with respect to the coupling rate to the free space leaky modes (W_{leaky}) is given by:

β=W_{cavity}/W_{leaky}=β₀·(Δω_{c})²/(4f(θ)²+(Δω)²)≡β₀×L.

Here Δω_{c}=ω_{c}/Q, ω_{c} is the NQD optical dipole frequency, Q is the quality factor of the resonant mode, f(θ)=2πC sin θ where C is the experimental slope of the dispersion relation ω(k)=Ck extracted from FIG. 1b for small k values. The dashed black line in FIG. 3a is a fit of the experimental data to the above formula. The best fitting was achieved for Q=23 and /beta₀=18.3. The fitted Q factor is in a good agreement with the estimation of Q=21.5 extracted from the numerically calculated near field distributions, such as the one shown in FIG. 3b. This justifies the above described physical principles. The large β and therefore the good directional beaming efficiency is achieved with a rather low Q-factor due to the small optical modal volume at resonance. An even better efficiency can be thus achieved by increasing Q by various means, such as using a less lossy metal in this wavelength range.

It is evident from the near field calculations of FIGS. 3a-3c that there is a strong spatial selectivity in the enhancement of the coupling of the NQD optical dipole transition to the resonant EM modes of the nanoslit array. This is because the EM enhancements of the optical resonances have a spatial variation within a unit cell, and NQDs that are positioned at different locations within a unit cell should feel a different EM field. In the case of the device 10 configuration of FIG. 1a, this selectivity is harder to isolate experimentally, as the NQDs are dispersed homogeneously within the resonant structure. A strong evidence for such spatial selectivity was obtained by investigating the angular emission spectrum from the sample in the device 100 configuration of FIG. 1c).

FIG. 4a presents the measured TM polarized angular emission spectrum of the monolayer sample 100 when the laser excitation is from the top of the sample. In this case, the excitation of the NQDs on the metallic surface is efficient. Again, a clear directional emission is observed, with the emission dispersion matching the air-metal SPP-like resonances seen in FIG. 1d. It is also seen that no emission is observed at the glass-metal SPP-like resonance. These air-metal SPP-like resonances are accompanied by strong localized resonant EM fields. In contrast to the resonant modes obtained with the device 10 configuration of FIG. 1a, the field enhancements here are localized close to the air-metal interface (hence the name SPP-like modes). This can be clearly seen in the near field calculation in FIG. 4c. This calculation refers to the forward directional emission point marked by the arrow in FIG. 4a. Two observations point toward the spatial selective coupling property. First, no directional emission was observed at the glass-metal SPP-like resonances. This is because the strong field enhancements in that case are localized mostly on the glass-metal interface, where no NQDs are present. Second, referring to FIG. 4b which presents the emission from the sample when the laser excitation was done from the glass side, it is shown that in this excitation geometry, in contrast to previous one, mostly the NQDs that reside in the bottom of slit of the metal grating (on the glass substrate) are excited. As can be seen in FIG. 4b, there is a very weak directional emission compared to the one observed when the laser excitation is from the air side. This is explained well by the field intensity distribution cross sections shown in FIG. 4d. It is clear that for the air metal SPP-like resonance only the NQDs in the air-metal interface (marked by point (A)) experience significant field enhancements and therefore directional emission, while the NQDs on the glass substrate at the bottom of the slit (point (B)) do not.

The inventors have found that for given emitter media (e.g. NQDs containing layer), i.e. given material composition and thickness of the layer, as well as core/shell structure in case of discrete emitters such as NQDs), the parameters of metallic nanoslit array can be appropriately selected to induce emission of photon(s) from each QD in a desired direction with a desirably small divergence angle. The parameters of the metallic nanoslit array including critical dimensions and density of the features of the metallic pattern and parameters of the dielectric structure (as described above) control the operating resonance wavelength and enhancement factor. The density of the QDs affects the number of photons emitted (single photon to multiphoton emission). For a one dimensional slit array, the directionality would be only in one axis; for a full directionality, a two-dimensional slit array structure can be used, for example slits with circular symmetry. The selection of these and other parameters and conditions of the structure is aimed at creating resonant coupling of the optical transition of the emitter media to the EM mode of the metallic nanoslit array structure.

As described above, the invention is based on the understanding that the eigenmodes of the patterned metallic structure result in localized electromagnetic field enhancements at the Bragg cavity resonances, and the photon beaming is achieved using the enhanced resonant coupling of the emitter media (e.g. quantum dots) to the Bragg cavity modes, which dominate the emission properties of the emitter media.

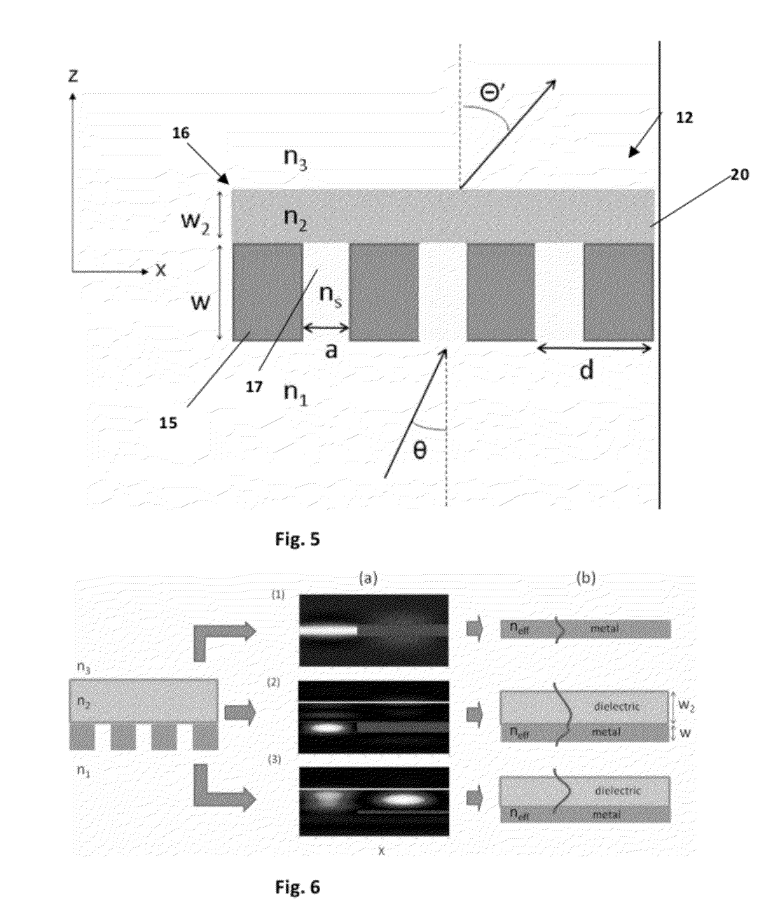

Reference is made to FIG. 5 showing the geometry of the patterned metallic structure 12 used in the device 10 configuration of FIG. 1a, and all relevant optical and material parameters. Here, n₁ and n₃ are the refractive indices of the infinite dielectric layers 14 before and after the grating 15, and nₛ is the refractive index inside the slits 17 between the metallic features; w is the thickness of the grating 15, d is the periodicity of the grating 15, and a is the width of the slit 17. A thin dielectric layer is added, with the refractive index n₂, and with thickness w₂ that is of the same order of magnitude as the grating thickness w. The incident plane wave vector and the transmitted wave vector are represented by the arrows.

Let us now derive a closed-form solution for the enhanced transmission (ET) maxima, based upon the approximations of the analytical model of the optical response of periodically structured metallic films. This closed-form solution is based on the condition of a standing wave in the subwavelength corrugated structure for the first Bragg order (the first diffraction order). This approximation leads to a mapping of the problem with the corrugated structure into one with a noncorrugated effective homogeneous dielectric layer replacing the grating, which is termed here an Effective Bragg Cavity (EBC) model. This mapping is shown in FIG. 6. This figure is a schematic illustration of the EBC model, showing (a) numerically calculated near-field intensity in a unit cell of the grating at a wavelength corresponding to an ET maximum in three different configurations, where the dielectric layer (when present) has effective refractive index n₂, (b) corresponding EBC model mapping. The same model applies to all the configurations, the only difference being is the area in which the standing wave appears in the structure, which is shown schematically for each configuration.

The derivation starts from the source-free Maxwell equations in an inhomogeneous medium:

$$\begin{matrix}∇ \times [ \frac{1}{μ ( r )} ∇ \times E ( r ) ] - {k}^{2} ∈ ( r ) E ( r ) = 0 , & ( 1 ) \\ ∇ \times [ \frac{1}{∈ ( r )} ∇ \times H ( r ) ] - {k}^{2} μ ( r ) H ( r ) = 0 , & ( 2 )\end{matrix}$$

where μ is the relative magnetic permeability and ∈ is the dielectric constant. The vacuum wave vector of the plane wave with a wavelength λ incident on the grating is k=2π/λ. The problem is now reduced to finding the eigenvalues of Eq. (2) in each of the four layers depicted in FIG. 5 separately, and then matching the boundary conditions. In the homogeneous dielectric layers before and after the grating, Eqs. (1,2) reduce to:

ΔE(r)+k²∈μE(r)=0.

ΔH(r)+k²∈μH(r)=0.|

producing the known wave equations in homogeneous dielectric media. Considering the TM polarization and utilizing the assumption of a 1D slit array, periodic along the x axis [with μ(r)=1 everywhere], the solution for the eigenfunctions of Eq. (2) for the magnetic field inside the grating will take the form of Bloch waves, because of the periodicity of the structure:

$${H}^{( j )} ( r ) = {\sum }_{m} {H}_{mj} {e}^{i [ ( {k}_{z} + gm ) x + {k}_{z}^{( j )} z ) \hat{y}} ,$$

where j indexes the eigenmode, g=2π/d, kₓ is the same as that of the incident electromagnetic wave, and k_{z}^{(j)} will be given from solving Eq. (2). The total magnetic field in the grating layer is calculated by taking the sum of all the Bloch-wave excitations:

$$H ( r ) = {\sum }_{j} {ψ}_{( j )} {\sum }_{m} {H}_{mj} {e}^{i \vert ( {k}_{z} + gm ) z + {k}_{z}^{( j )} z \vert \hat{y}} . \qquad ( 3 )$$

with Ψ₍ⱼ₎ denoting the excitation coefficient of the jth eigenmode inside the grating. In layers 1 and 3, which are homogeneous dielectric layers before and after the grating, the eigenmode solutions are just

$${H}_{1 ; 3} ( r ) = {\sum }_{m} {A}_{m}^{1 ; 3} {e}^{i [ ( {k}_{z} + gm ) x +} {\text{?}}^{z ] \hat{y}} . \\ \text{?} \text{indicates text missing or illegible when filed}$$

with k_{z} given by

k_{z}^{1,3}=\sqrt{(k_{1,3})²−(k_{1,3} sin θ+gm)²}

where

k_{1,3}=k₀n_{1,3}|,

θ is the incidence angle depicted in FIG. 5, and n_{1;3}=∈_{1;3}^{1/2} is the refractive index of the homogeneous layers before and after the metallic grating, respectively.

Finding the z components of the wave vectors inside the grating, k_{z}^{(j)} can be done using numerical calculations (e.g., RCWA solution). An analytic solution can be achieved by noticing that in the subwavelength regime (λ/nₛ>2a), there is only one propagating mode inside the slits of the grating. This mode will be denoted by k_{z}^{prop}. Using the approximation that this is the only excited mode by the incoming wave (i.e., discarding the evanescent modes inside the grating), Eq. (3) becomes

$$H ( r ) = {\sum }_{m} {H}_{m} {e}^{i [ ( {k}_{z} + gm ) x + {k}_{z}^{prop} z ] \hat{y}} . \qquad ( 4 )$$

and we can define kₓ^{m}=kₓ+gm.

Now, given that the incident light is normal to the grating (i.e., θ=0 in FIG. 5), the Bloch mode in Eq. (4) becomes a superposition of wave functions with kₓ^{m}=kₓ+gm, for all integer values of m. Under the approximation of a perfectly conducting metal, solving the boundary conditions between the layers will lead to approximate analytical solutions of the electromagnetic fields in the different layers and to the approximated full transmission spectra of the structure.

However, instead of exactly solving these equations, one can intuitively identify the cause for the ET: under the condition that the wavelength of the incoming light satisfies λ/n_{1;3}>d (which means k_{1;3}<g), there can be only one propagating mode outside of the grating, having kₓ^{m}=0 (this is just the zero-order Bragg mode), while all the modes having kₓ^{m}=kₓ+gm with m≠0 are evanescent. On the other hand, inside the grating, viewing the excited Bloch mode as a superposition of plane waves with kₓ^{m}=gm (each plane wave corresponds to a different value of m), all these plane waves are propagating, even those with m≠0, as is clearly seen in Eq. (4). Hence, these modes, which are evanescent outside the grating, will be confined to the grating. Again, from Eq. (4), it is seen that all these plane waves have k_{z}=k_{z}^{prop}, for all values of m, even though kₓ=gm≠0.

The general condition for a standing wave including all the different Bragg orders with these approximations can be solved analytically with the approximation of a perfectly conducting metal, including all orders of m. However, when the slit width a is of the same order of magnitude as the slit periodicity d, which means one can, with good accuracy, take only excited modes with m=1, a much simpler picture emerges: this problem can be mapped into a similar one by replacing the metallic patterned structure with a dielectric material whose refractive index is defined as

$${n}_{eff} = \frac{\sqrt{{( {k}_{z}^{prop} )}^{2} + {g}^{2}}}{k} . \qquad ( 5 )$$

For normal incidence light in the TM polarization, k_{z}^{prop}=nₛk, thus we get that

\check{n}_{eff}=\sqrt{nₛ²+(λ/d)²}|

With this mapping, the boundary matching condition in the metallic grating is the same as the boundary condition for a slab waveguide mode in the homogeneous effective dielectric medium with n=n_{neff}, surrounded by two lower refractive index dielectric layers, n₁ and n₃. Thus, the standard slab waveguide transverse resonance condition

2k_{z}^{prop}ω−2φ₁₂−2φ₂₃=2πl, (6)

will give us the values of k that produce the standing wave inside the grating layer for m=1. This resonant k will be denoted by k₀^{r}. The boundary phases φ₁₂ and φ₂₃ are given by

φ₁₂=tan⁻¹(\hat{γ}/k_{z}^{prop}),

φ₂₃=tan⁻¹(\hat{δ}/k_{z}^{prop}),|

\hat{γ}=|(n_{eff}/n₁)²\sqrt{g²−(n₁k₀^{r})²},|

\hat{δ}=(n_{eff}/n₃)²\sqrt{g²−(n₃k₀^{r})²},|

with n_{eff} given by Eq. (5), and l is a nonnegative integer. For the specific case where nₛ=n₁=n₃, we get an even simpler form:

φ₁₂=φ₂₃=tan⁻¹((χ²+1)\sqrt{χ²−1}) (7)|

with χ=g/(nₛk₀^{r}).|

When solving for incoming TE polarized plane waves, the derivation is similar, though one should start from Eq. (1) instead of Eq. (2). By using a similar procedure we get an equation similar to Eq. (6), the TE slab waveguide transverse resonance. The only changes from the above TM case are

\hat{γ}=\sqrt{g²(n₁k₀^{r})²},

\hat{δ}=\sqrt{g²−(n₃k₀^{r})²},

and k_{z}^{prop} is calculated as will be explained below. Therefore, Eq. (6) is general and applies for both polarizations.

Considering emergence of ET in TE polarization with a thin dielectric layer, Eq. (6) gives the Bragg diffracted standing waves, and, thus, according to the EBC model, also the ET condition. The one major difference for an incoming light in the TE polarization is that k_{z}^{prop} behaves differently than in the TM polarization because of the slab waveguide boundary conditions: approximating the grating slits to an infinite metallic slab waveguide (with a correction to the width a in case of nonideal metal to account for skin depth), gives an equation for calculating k_{z}^{prop}:

$${k}_{z}^{prop} = \sqrt{\frac{μ ∈}{{c}^{2}} {ω}^{2} - {γ}^{2}} . \qquad ( 8 )$$

with γ=πm/a. This approximation for k_{z}^{prop} can be verified by comparing the propagating k_{z} found numerically in rigorous numerical calculations with the one given by Eq. (8). The approximation holds remarkably well as long as the imaginary part of the propagating k_{z} is small, which is valid as long as λ/ns<2a.

From Eq. (8) it is clear that there is a cutoff wavelength. Hence, in the subwavelength regime ((λ/nₛ)≧2a) k_{z}^{prop} becomes imaginary and there are no propagating modes inside the grating. Thus, no standing wave is possible inside the metallic grating in this regime and no ET can be observed. However, an addition of a thin dielectric layer on top of the grating allows for a standing wave in the system even for λ/nₛ>2a, given that λ/n₂<d. This is because, under these conditions, while there is no longer a propagating mode inside the grating, the thin dielectric layer (with refractive index n₂) can still support one, allowing for a standing wave in the thin dielectric layer. In this case, the grating acts as one of the boundaries.

Therefore, in the TE polarization with a thin added dielectric layer, there are two regimes where ET can occur. (I) For the nonsubwavelength regime [i.e., (λ/nₛ)<2a], where there is a propagating mode for the first Bragg order (m=1) for both the grating and the thin dielectric layer n₂, the standing wave will be in both these layers, and is given by the equation for a two layer dielectric waveguide (with n₂ and n_{eff} for the grating layer), corresponding to FIG. 6(b)(2). (II) For the subwavelength regime, where there is no propagating mode in the grating [(λ/nₛ)>2a], the thin dielectric layer can still support a propagating mode for the first Bragg order, given that λ/n₂<d. Even though there is no propagating mode in the grating, there will still be an evanescent eigenmode with a relatively small imaginary wave vector [as long as (λ/nₛ) is only slightly larger than 2a], which will be denoted by k_{z}^{ev}, which can be either estimated or calculated numerically (using the RCWA method, for example). Thus, for thin gratings, an evanescent coupling of the first Bragg diffraction to the waveguide mode in the thin dielectric layer will still be possible. Then, only the first Bragg order can be considered, and the solution for a standing wave inside the dielectric layer n₂ can be found: for mapping the grating into a homogeneous dielectric layer Eq. (6) can be used for finding the standing wave condition, with the changes

k_{z}^{prop}=\sqrt{(n₂k₀^{r})²−g²},|

\hat{γ}=\sqrt{g²−(n₁k₀^{r})²},|

and

\hat{δ}=Im(k_{z}^{ev})

The inventors have shown that the maximum transmission peaks observed in this configuration indeed satisfy the EBC condition of Eq. (6) (with the standing wave occurring in the dielectric layer), corresponding to the configuration in FIG. 6(b)(3).

Thus, the observed ET resonances in the two configurations are intuitively explained by the same EBC model, as arising from various ways of fulfilling the waveguide condition of Eq. (6). Therefore, it is evident that all these distinct effects have the same underlying mechanism. The inventors have shown, and it will be described below that the predictions of the EBC model are in a very good agreement with exact numerical calculations, confirming the validity of the above effects.

So far the resonant standing wave condition for the Bragg diffractions is derived. We can stress that the condition on the wavelength of an ET resonance, in both TM and TE polarization, is the same: the ET resonant wavelength is the one that solves the effective waveguide confinement analytic condition of Eq. (6). As in a Fabry-Perot cavity, these standing wave conditions have a visible effect on the transmission: the resonant standing waves for the higher Bragg orders (m≠0) will cause the forward transmission to be at maximum value, because of their constructive interference with the propagating m-0 mode. This is similar to the effect of reflection resonances in dielectric grating waveguide structures. Since generally the waveguide condition is transcendental, it is difficult to show analytically that the standing wave condition [Eq. (6)] and the ET condition are identical. However, it was shown that, for a range of different configurations, with incoming light in either TE or TM polarization, the wavelength λ₀, for which an ET maxima occurs in rigorous numerical calculations, matches well the analytical equation for the standing wave condition [i.e., Eq. (6)]. Therefore, this simplified model suggests that, for there to be ET, there has to be a standing wave in the z direction inside the system for the Bragg modes having m≠0. The ET resonance condition is, therefore, approximately given by Eq. (6). This, in essence, is the EBC model. This simple model predicts correctly the emergence of ET in a vast variety of ID configurations, in both TE and TM polarizations, and for the subwavelength and nonsubwavelength spectral regimes, using the same analytical condition [Eq. (6)]. The only difference between these different configurations is the effective region where this standing wave occurs, as will be described below. Therefore, this picture well portrays the general underlying mechanism behind ET in such grating structures. It should be noted that, while taking higher orders of m into consideration makes it difficult to map the problem to the dielectric picture, under the approximation of a perfectly conducting metal, it is still possible to find a closed-form solution using all orders of m.

Turning back to FIG. 6, it shows a schematic representation of the EBC model. Three different standing wave configurations are depicted: panels (1)-(3) in FIG. 6(a) show the numerically calculated near-field intensity for an incoming λ at an ET maximum in the different configurations. These configurations are summarized in Table 1 below.

| Configuration | Layer n₂ | Polarization | Spectral Range |
|---|---|---|---|
| (1) | not present | TM | all |
| (2) | present | TE | λ/nₛ < 2a |
| (3) | present | TE | λ/nₛ > 2a |

Panels (1)-(3) in FIG. 6(b) show schematically the EBC model mapping, with the standing wave that corresponds to each of the following configurations:

(1) a bare grating with the incident plane wave in the TM polarization (here both the dielectric materials n₁, n₃ are approximated as having infinite thickness). In this case, the standing wave is contained in the metallic grating layer.

(2) the nonsubwavelength regime (i.e., λ/ns<2a), an incoming plane wave in the TE polarization with an added dielectric layer n₂ with a finite thickness, of the same order of magnitude as the metallic grating thickness. Here, the standing wave is in both the metallic grating and the thin dielectric layer n₂.

(3) the subwavelength regime with the incoming plane wave in the TE polarization and the dielectric layer n₂ having a finite thickness. This regime corresponds to λ/nₛ<2a and λ/n₂<d, which allows for a standing wave solely in the thin dielectric layer.

It is clear from FIG. 6(b) that the model mapping is essentially the same for the two configurations, with the only difference being the area that confines the standing wave at the ET resonances. The model shows the appearance of ET resonances also in TE polarization.

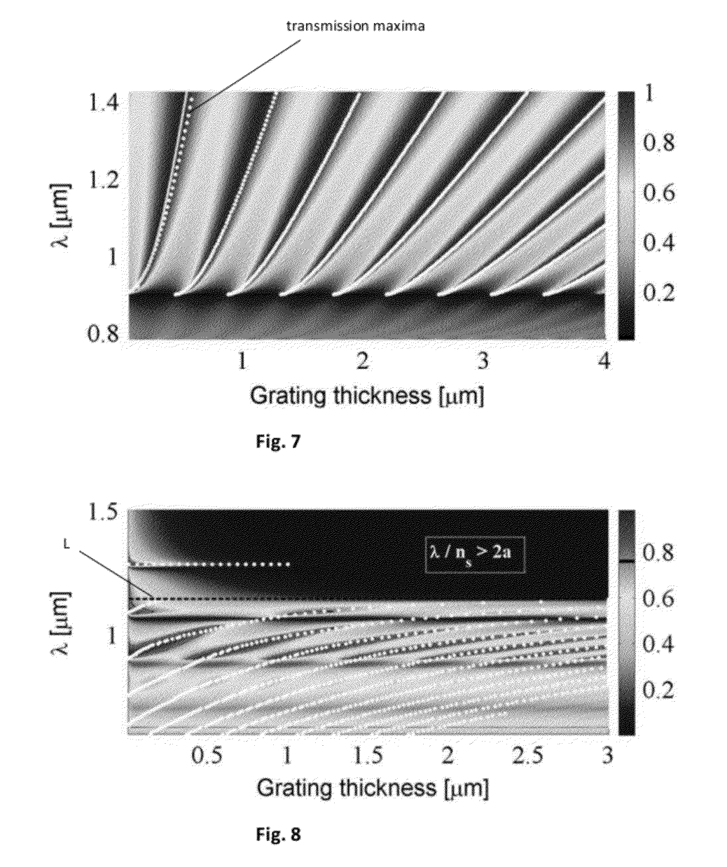

Let us now compare the model results for the spectral position of the ET maxima, to a full numerical calculation using an RCWA method. Two different cases are compared: incoming light in the TM polarization with a bare metallic grating, and in the TE polarization with an added thin dielectric layer. It can be shown that, in both these cases, the EBC model correctly provides all occurrences of ET with a good accuracy. In this connection, reference is made to FIG. 7 showing numerically calculated zero-order transmission in the TM polarization with no added thin dielectric layer, in the symmetric configuration n₁=n₃=nₛ, for different wavelengths and grating thicknesses. The dotted while lines are the transmission maxima according to the EBC model for m=1 (the first diffraction order) only; the yellow line is the first transmission maximum according to the EBC model with all the diffraction orders taken into account. This numerically calculated zero-order transmission intensity for normal incident light for different wavelengths and grating thicknesses, corresponding to the configuration depicted in FIG. 6(b)(1). The relevant parameters for the numerical calculation were d=0.9 μm, the slit width is a=0.35 μm, and n₁₌ₙ₃=nₛ=1 on both sides of the grating and inside the slits. It can be seen that there exists a very good agreement between the numerically calculated ET and the EBC model predictions, with no fitting parameters.

It is apparent from FIG. 7 that changing the grating thickness changes the wavelength for which the transmission maximum occurs as expected from a cavitylike behavior. Furthermore, FIG. 7 shows clearly that, in the long wavelength regimes, the dependence of the resonant wavelength on the cavity width is linear, w=λ₀l/2nₛ (l being an integer), similar to Fabry-Perot cavities. This corresponds to the slit-cavitylike ET regime, and a near-field inspection indeed shows that the highest local field intensities are inside the slits. On the other hand, the resonance behavior at shorter wavelengths shows a deviation from this linear slope, and correspond to an SPP-like maximum (with the local field intensities being high inside the slits and outside of it, as well). As seen, this transition between the two regions is predicted by the EBC model. Indeed, since in this case we have n₁=n₃=nₛ, then in the limit where λ/n₁ [symbol] d, we get n_{eff} [symbol] n_{1;3} and χ [symbol] 1. Therefore, in this limit, Eq. (7) becomes

φ₁₂=φ₂₃≈ tan⁻¹(χ³)≈π/2|

and Eq. (6) reduces to

2nₛk₀w=2πl,|

which is the pure metallic slab waveguide condition, or

$$w = \frac{{λ}_{0} l}{2 {n}_{s}} .$$

with 1∈N, as in a typical Fabry-Perot resonance. This means that the standing wave is confined exactly inside the metallic grating, corresponding to the slit-cavity-like ET maxima, and to the longer wavelength regions in FIG. 3. The other limit, where λ/nₗ→d, gives a confined mode with an effective length in the z direction that is much larger than the grating thickness w. This limit corresponds to the SPP-like maxima: due to the slow spatial decay of the field intensity of the confined mode into the surrounding dielectric layers in this limit, the near-field intensity distribution behaves as an SPP-like mode. In this sense, the cavitylike modes and the SPP-like modes are just two limits of the general EBC model.

It should be noted that the above effect is not very sensitive to the fact of whether the metal is approximated as a perfectly conducting metal or treated as a real metal with absorption, as well. While the specific quantitative transmission intensity does change, the ET occurs at almost the same wavelengths both in the numerical calculation and in the EBC model. Therefore, the imaginary part of the dielectric index plays only a secondary, weak role in the emergence of ET in the TM polarization in 1D slits, as opposed to the case of SPP resonances on flat real metals.

Reference is made to FIG. 8 showing a similar graph for the TE polarization, where a thin dielectric layer was added. The relevant parameters are d-0.9 μm, a=0.35 μm, w₂=0.93 μm, n₁=n₃=1, and n₂=1.52. As can be seen, in the nonsubwavelength regime [(λ/nₛ)<2a, corresponding to the region beneath line L], the maximum transmission lines behave as expected from configuration (b) in FIG. 6, the cavity in this case is the grating layer + the thin dielectric layer n₂. However, it can also be seen that ET is observed in the subwavelength regime (above line L), again, with a very good agreement with the EBC model evanescent coupling predictions, discussed above with reference to FIG. 6(c). It should be noted that the extra observed features of transmission minima lines closely correspond to the waveguide condition in the thin dielectric layer n², when taking the grating as a homogeneous metallic slab. Accordingly, these minima do not change with the metal width. Also, it should be noted that in the subwavelength regime, the transmission maximum does not change spectrally with the metal thickness. This is because there is no propagating mode in the grating, as described above.

In both polarizations, the EBC model predicts quite accurately the behavior of the ET, but with a small deviation from the actual maximum. This can mostly be explained by the approximation that takes into account only the first Bragg order. The first transmission maxima in FIG. 7 is the EBC model's calculated first transmission maximum when all the Bragg orders of the waveguide condition are taken into account. As can be seen, this improves the accuracy of the model's prediction. Furthermore, as was previously shown, taking only the propagating mode inside the grating into account already causes a small shift of the transmission features. The inventors have also compared the EBC model to numerical calculations in which n1≠n3. In the spectral regimes where all the higher Bragg diffraction orders are evanescent in both infinite dielectric layers (layers 1 and 3), the agreement with the analytical model was just as good, although the ET maximum was less well defined in the numerical simulations. When one of the dielectric layers starts supporting a propagating mode with m≠0, no real ET is apparent.

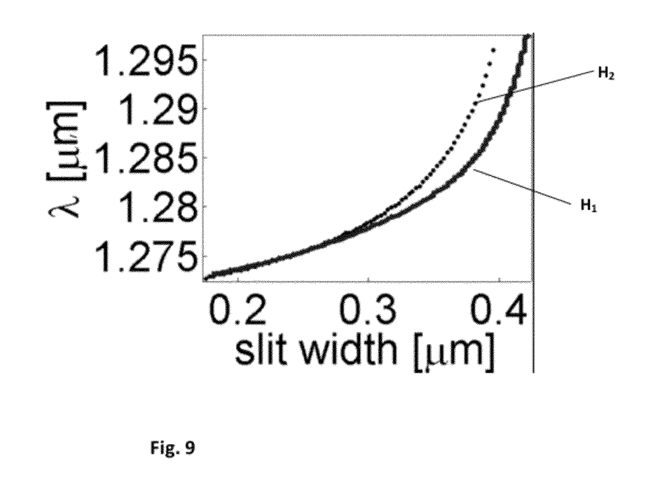

Reference is made to FIG. 9 exemplifying that by changing the slit width a, the properties of the evanescent wave in the slits can be changed. In FIG. 9, the zero order transmission maxima is extracted from the numerical model for different values of the slit width a in the subwavelength regime, and is compared to the predicted value given by the EBC model. In the figure transmission maxima according to the RCWA is presented by graph H₁ and the EBC model is presented by graph H₂. Here, the transmission minimum is at l=1.266 mm. the periodicity is d=0.9 mm, the grating thickness is w=0.25 mm and the dielectric layer thickness is w2=0.25 mm. As can be seen, there is a good correspondence between the numerical model and the predicted value given by the EBC model.

Thus, by appropriately selecting one or more parameters of the patterned metallic structure, the standing wave can be created at a location where the emitter media is embedded in the structure to thereby obtain desired directional parameters of radiation output of the structure.

1. An emitter device for emitting electromagnetic radiation, the device comprising a metallic patterned structure, and emitting media which is integral with the metallic patterned structure, wherein the emitting media comprises one or more emitters of omni-directional emission in nature wherein certain emission pattern, and one or more parameters of the metallic patterned structure defining a dispersion map thereof are selected according to the emitting pattern of the emitting media such that the metallic patterned structure operates as a beam shaper creating resonant coupling of each of said one or more emitters of the emitting media with a microscopic confined optical mode of the metallic patterned structure thereby enhancing by a predetermined enhancement factor the emission from the emitting media in a predetermined direction, the device thereby providing predetermined directional beaming of output electromagnetic radiation characterized by a predetermined angular propagation of the electromagnetic radiation emitted by the emitting media.

2. The device of claim 1, wherein the emitting media comprises a layer containing said one or more emitters embedded therein.

3. The device of claim 2, wherein said one or more emitters comprise at least one of the following: quantum dot, quantum wire, quantum well.

4. The device of claim 1, wherein the emitting media comprises a bulk-layer material.

5. The device of claim 2, wherein the emitting pattern of the emitting media is defined by the emitters' distribution with the emitter containing layer.

6. The device of claim 2, wherein the emitting pattern of the emitting media is defined by a thickness of said layer.

7. The device of claim 5, wherein the emitting pattern of the emitting media is defined by a thickness of said layer.

8. The device of claim 1, wherein the metallic patterned structure comprises a dielectric structure and a pattern of spaced-apart metallic features embedded in the dielectric structure.

9. The device of claim 8, wherein said dielectric structure is a single- or multi-layer dielectric structure.

10. The device of claim 1, wherein the emitting media is located on an outer surface of the metallic patterned structure.

11. The device of claim 8, wherein the emitting media is embedded in the dielectric layer structure of said metallic patterned structure, being above or below said pattern or in between the metallic features.

12. The device of claim 8, wherein said one or more parameters of the metallic patterned structure defining the dispersion map thereof include at least one of the following: critical dimensions of the metallic pattern; density of the metallic features of said pattern, material composition of the metallic patterned structure, layout of said metallic patterned structure.

13. A method for providing predetermined directional beaming of electromagnetic radiation having a predetermined angular propagation of the electromagnetic radiation, the method comprising:
selecting emitting media formed by one or more emitters of omni-directional emission in nature having a predetermined emitting pattern;
providing a metallic patterned structure of a predetermined dispersion map selected in accordance with said emitting pattern; and
integrating said emitting media in said metallic patterned structure, thereby creating resonant coupling of each of said one or more emitters of the emitting media with a microscopic confined optical mode of the metallic patterned structure thereby enhancing by a predetermined enhancement factor the emission from the emitting media in a predetermined direction and angular distribution.

14. An emitter device for directional emission of electromagnetic radiation propagating in a predetermined direction and a predetermined angular distribution, the device comprising emitting media for emitting electromagnetic radiation with a certain emitting pattern, the emitting media comprising one or more emitters each of omni-directional emission in nature embedded in a metallic patterned structure, wherein the metallic pattern structure has a predetermined dispersion map selected according to the emitting pattern of the emitting media such that each of said one or more emitters of the emitting media is in resonant coupling with a microscopic confined optical mode of the metallic patterned structure, a device output being formed by said electromagnetic radiation propagating with the predetermined direction and the predetermined angular distribution.

15. An emitter device comprising emitting media for emitting electromagnetic radiation with a certain emitting pattern, the emitting media comprising one or more emitters each of omni-directional emission in nature embedded in a metallic patterned structure, wherein the metallic pattern structure has a predetermined dispersion map selected according to the emitting pattern of the emitting media to provide beam shaping to radiation being emitted wherein at least one of the following: polarized emission of the emitting media having different general direction of propagation and angular distribution for TE and TM polarization modes, altering spontaneous emission rate of the emitting media, and a desired number of photons in an output beam of the device.

16. A system for generating electromagnetic radiation, the system comprising the emitter device of claim 1 and an exciting unit configured and operable for exciting the emitting media in the emitter device to emit electromagnetic radiation with a certain emitting pattern.
